(19) United States
(12) Patent Application Publication
(10) Pub. No.: US 2013/0200918 A1
(43) Pub. Date: Aug. 8, 2013

(54) TESTING APPARATUS FOR PHOTOVOLTAIC CELLS

(71) Applicants: Leonid Borisov Rubin, Burnaby (CA); Vasily Yefimovich Tarasenko, Burnaby (CA); Alexander Sergeevich Osipov, New Westminster (CA); Valery Michaelovich Nebusov, Burnaby (CA); Rainer Grischke, Vancouver (CA); Bram Michael Sadlik, Vancouver (CA)

(72) Inventors: Leonid Borisov Rubin, Burnaby (CA); Vasily Yefimovich Tarasenko, Burnaby (CA); Alexander Sergeevich Osipov, New Westminster (CA); Valery Michaelovich Nebusov, Burnaby (CA); Rainer Grischke, Vancouver (CA); Bram Michael Sadlik, Vancouver (CA)

(73) Assignee: DAY4 ENERGY GROUP INC., Burnaby, BC (CA)

(21) Appl. No.: 13/880,022

(22) PCT Filed: Oct. 18, 2010
(86) PCT No.: PCT/CA2010/001664

§ 371 Date: Apr. 17, 2013

(51) Int. Cl. G01R 31/26

(52) U.S. Cl. CPC G01R 31/2605
USPC 324/761.01

(57) ABSTRACT

The present invention allows simultaneous measurement of current and voltage produced by a PV cell by removably pressing first and second parallel spaced apart closely adjacent sensing conductors, electrically insulated from each other, onto a current carrying conductor on a front side of the PV cell to make electrical contact therewith, while removably pressing at least one reference contact to a reference conductor on the rear side of the PV cell to make electrical contact therewith. Current is conducted from the current carrying conductor on the front side, through the first sensing conductor to current measuring circuitry and through the at least one reference contact back to the rear side reference conductor. Voltage is sensed at the second sensing conductor relative to the rear side reference conductor, using voltage measuring circuitry.

### BACKGROUND OF THE INVENTION

1. Field of Invention

This invention generally relates to determining electrical characteristics of photovoltaic (PV) cells and more particularly to test equipment and methods and apparatuses for simultaneous measurement of current and voltage output of PV cells.

2. Description of Related Art

Under light illumination, photovoltaic (PV) cells generate electric power that is collected from the cell by front and rear electrical contacts. The front contact typically comprises a plurality of narrow screen printed lines known as “fingers”, all connected to each other by two wider screen-printed lines referred to as “bus bars”. The fingers collect electrical current from the PV cell itself and the bus bars receive the current from the fingers and transfer it away from the cell.

Typically, each screen printed finger has a width of between 90 to 120 microns and a height of between 10 and 30 microns. The fingers are typically spaced apart by about 1.5 to 3 mm. Each screen printed bus bar has a width of between 2 to 3 mm, a height of between 15 and 30 microns and a spacing between neighboring bus bars of typically 35 to 70 mm.

The rear side electrical contact normally covers the entire rear surface of the PV cell and is made from screen printed metallic material such as aluminum paste, except for a few small areas containing screen printed paste containing silver to form what are referred to as “silver pads”. The area covered by aluminum facilitates collecting electric current from the rear side of the PV cell and passes it to the silver pads that act as rear side or reference terminals of the PV cell.

When producing conventional PV modules manufacturers interconnect a plurality of PV cells in series by soldering tinned copper ribbons to the bus bars on the front of one cell and to the silver pads on the back of an adjacent cell.

The maximum power that can be generated by a PV cell depends on the cell's intrinsic characteristics and external load. The maximum efficiency of a PV module can be achieved if all PV cells in the module have similar electrical characteristics. Therefore, in manufacturing, PV cells must be tested to determine their electrical characteristics, this is to facilitate sorting in order to identify PV cells with common electrical characteristics to be used in a module to achieve maximum module efficiency. The testing equipment for this purpose takes precision simultaneous measurements of electric current (I) and voltage (V) at various conditions of external electric load under standard light illumination. There are several companies that manufacture such equipment, including for example, Berger Lichttechnik GmbH & Co. KG, lsarstrasse 2 D-82065 Baierbrunn, Germany Tel.: +49(0)89/793 55 266 E-mail: infobergerlichttechnik.de; BELVAL SA Sous-la-Roche, PO Box 5 CH-2042 Valangin, Switzerland, Tel.: +41 32 857 23 93 Fax :+41 32 857 22 95 Email info©belval.com; and H.A.L.M. Elektronik GmbH Sandweg 30-32 D-60316 Frankfurt am Main, Germany, Tel.: +49 069-943 353.0.

Conventional testers comprise several parts, including a pulse or continuous light source for sunlight simulation, an electric contacting measuring unit and an electronic processing unit. The electric contacting measuring unit is intended to make reliable low resistance electrical contact with the bus-bars on the front side of a PV cell under test and with the silver pads on the rear side of the PV cell under test to collect and measure values of electric current and voltage from the PV cell as a function of external load. The electronic processing unit performs a sweep through various external electric loads while simultaneously determining I and V values for various external load values. These I and V values are plotted as an I-V graph that allows the main characteristics of the PV cell, including but not limited to, short circuit current, (Isc), open circuit voltage (Voc), fill-factor (FF), maximum power point (Pmax), electric current at maximum power point (Imax), voltage at maximum power point (Vmax), shunt resistance (Rsh), and series resistance (Rs) to be determined. Measurement accuracy of all of the above values is extremely important for group sorting of PV cells into certain power or efficiency classes.

The accuracy of these measurements depends on the quality of the contact between the measuring unit and the PV cell under test, conductivity of current and voltage collecting terminals and on the circuits used to effect simultaneous measurement of I and V during PV cell testing. Modern crystalline silicon PV cells typically can generate high short circuit current values (Isc) of up to about 9 A at rather low open circuit voltages (Voc) of between about 600 mV to about 720 mV. Simultaneous precision measurement of I and V values, particularly voltage values accurate to within a few millivolts, is not a trivial task at such high currents.

Most PV cell testers comprise two or three solid metallic (usually brass) plates for contacting front and rear sides of a PV cell to be tested. The width of the metallic plate is usually about the same as the width of screen printed bus bars on the PV cell and typically does not exceed about 2 mm, to prevent unnecessary shading of the light illuminated area of the PV cell during testing.

These plates often hold a plurality of spaced apart pairs of spaced apart gold-plated measuring tips, each pair comprising a current measuring tip for measuring electric current and a voltage measuring tip for measuring voltage. The pairs may be spaced apart from each other by about 10-20 mm for example. Each measuring tip comprises a housing, a circular contacting head having a diameter of about 1-3 mm and a pressure equalizing spring located between the housing and the contacting head. The circular contacting head generally has a sharp edge and is plated with gold to minimize contact resistance with the PV cell under test.

When the metallic plate is mechanically pressed toward the surface of the PV cell, the sharp edges of the contacting heads are firmly pressed onto the bus bars while similarly configured reference contact heads contact silver pads on the rear side of the PV cell, thereby reducing the risk of breakage of the PV cell due to sufficient pressure counterbalance. Generally, equal pressure is applied by the heads on opposite sides of the PV cell.

The PV cell is then exposed to PV light illumination and electric current is collected from the front of the PV cell by the screen printed fingers and is received at the bus bars. Electric current is then collected from the bus bars by the current measuring tips of each pair and is finally passed to a front side solid metallic plate to which current measurement circuitry is connected. At the same time, the voltage measuring tips are connected to voltage measurement circuitry independent of the current measurement circuitry. The silver pads on the rear side of the PV cell are contacted by reference contact heads in corresponding positions to the current and voltage measurement heads. The contact heads are connected to the current and voltage measurement circuitry through a rear side metallic plate to complete respective current and voltage measurement circuits comprising the PV cell. The use of the plurality of contact heads to contact the bus bars and silver pads provides a low resistance contact that provides for reasonably accurate measurement of the current and voltage produced by the PV cell.

The above described PV cell testing equipment is currently widely used in industry for conventional screen printed PV cell testing. However, it cannot be used to test newer types of PV cells that have isolated screen printed fingers without bus-bars on their front side and no silver pads on their rear sides. The screen printed fingers of this type of cell may have a width of as low as 50 μm for example. This type of PV cell has several advantages including substantially higher efficiency than that of conventional PV cells with bus-bars, due to reduced shading of the front surface resulting from the lack of bus bars. In addition, this new type of cell eliminates the need to provide silver pads on the rear of the PV cell which leads to better back surface field (BSF) properties and increases the short circuit current (Isc) and open circuit voltage (Voc) of the PV cell. See, for example, PCT Application No.

It is not practical to use a plurality of measuring tips of the type described for conventional PV cells with bus bars to contact isolated screen printed fingers on the newer types of PV cells because the diameter of individual contacting heads is normally greater than the finger width (as low as 50 μm). Inevitably, the sharp edges of the contact heads will contact the cell surface and penetrate the front of the cell, thereby damaging the p-n junction under the surface. Smaller contacting tip heads are also problematic because it is practically impossible to maintain a precise shape, spacing and positioning of fingers during screen printing which would make it difficult to accurately and repeatably align contacting heads with the very narrow fingers on each PV cell to be tested.

PV cells are typically sold under a certain dollars per watt output formula, and therefore manufacturers need to know the total power output of any given PV cell to determine the price of the cell. Existing technologies for determining total power output of conventional PV cells are well known, as exemplified by the PV cell testing equipment described above, but existing test equipment cannot be used in its current form to test the newer type of isolated finger PV cells, due to the lack of bus bars on these cells.

US patent application Publication No. U.S. 2007/0068567 A1 filed Sep. 23, 2005 and published Mar. 9, 2007 entitled “Testing Apparatus and Method for Solar Cells” to Leonid Rubin et al. describes a method for temporarily electrically coupling to each of a plurality of current gathering fingers on a surface of a PV cell to facilitate testing of the PV cell. The method involves pressing a flexible elongated electrical conductor onto the surface of the PV cell such that an elongated contact surface of the electrical conductor extends across the surface of the PV cell to make electrical contact with substantially all of a surface of a bus connected to the fingers or at least a portion of each of the fingers, or both. Unfortunately this method does not provide for simultaneous and accurate measurement of current and voltage values because, for example, voltage is measured in a circuit comprising components of the test apparatus that also carry current produced by the cell, which creates a voltage drop in such components that is added to the actual voltage seen at the fingers.

U.S. Pat. No. 6,077,091 entitled “Surface Mounted Package Adapter Using Elastomeric Conductors” to McKenna-Olson et. al. discloses flexible elastomeric conductors for making electrical contact with corresponding rows of leads extending from an integrated circuit flat pack. However there is no suggestion as to how it could provide for simultaneous precision measurements of electric current and voltage from an illuminated PV cell having isolated fingers.

U.S. Pat. No. 6,741,087 B2 entitled “Voltage-Applying Probe, Apparatus for Measuring Electron Source Using The Probe, and Method for Manufacturing Electron Source Using Apparatus” to Akihiro Kimura et al. discloses a probe for applying a voltage to lines provided on a substrate. The probe comprises a conductive sheet, including a mesh sheet in which linear members are woven into a mesh and a conductive material which coats the mesh sheet, an elastic member for pressing the conductive sheet against the lines, and a holding member for holding the conductive sheet and the elastic member together. Although this type of probe has been designed specifically for testing performance of microelectronic devices there is nothing to suggest it can be used or adapted to support simultaneous precision measurements of electric current and voltage from an illuminated PV cell having isolated fingers.

U.S. Pat. No. 5,543,729 entitled “Testing Apparatus and Connector for Liquid Crystal Display Substrates” to Francois Henley discloses an electrical contacting probe that comprises an elastic member that is wrapped with wire or a mesh to provide uniform electrical contact with a substrate. The elastic member is compressible, allowing pressure to be applied to make a firmer contact, without damaging the contact points on the substrate. This type of probe has been designed specifically for testing performance of liquid crystal display substrates. There is nothing to suggest it can be used or adapted to support simultaneous precision measurements of electric current and voltage from an illuminated PV cell having isolated fingers.

None of the above described equipment and methods appears to provide for simultaneous and precision accurate measurements of electric current and voltage produced by isolated finger PV cells under illumination.

The present invention addresses this need.

### SUMMARY OF THE INVENTION

The present invention may provide for simultaneous measurement of current and voltage produced by a PV cell at its current carrying conductors, i.e. fingers, on the front side of the cell and eliminates or reduces the deleterious effects of losses due to wires connecting the PV cell under test to test equipment. In one embodiment, this is achieved by removably pressing first and second parallel spaced apart closely adjacent sensing conductors, electrically insulated from each other, onto the current carrying conductors to make electrical contact therewith, while removably pressing at least one reference contact to a reference conductor on the rear side of the PV cell to make electrical contact therewith. Current is conducted from the current carrying conductors through the first sensing conductor to current measuring circuitry and through the at least one reference contact back to the rear side reference conductor. Voltage is sensed at the second sensing conductor relative to the rear side reference conductor, using voltage measuring circuitry. Because the first and second sensing conductors are long, parallel and spaced apart but closely adjacent to each other they can contact a plurality of spaced apart fingers on a PV cell all at the same time and this can collect current directly from the fingers while at the same time sensing voltage at all of the fingers, without any need for precision alignment of the sensing conductors to coincide with bus bars.

This method is suitable for testing newer type PV cells with no front side bus bars, but may also be used with conventional PV cells that employ bus bars for current collection by pressing the first and second sensing conductors onto a bus bar.

The first and second sensing conductors may be mounted on a probe, for example. Where PV cells with bus bars are to be tested, the first and second sensing conductors are spaced apart no wider than the bus bar on which they are intended to be pressed to ensure that both the first and second sensing conductors simultaneously contact the same bus bar when pressed thereon.

PV cells with bus bars have at least two bus bars and therefore two separate probes bearing the above described first and second sensing conductors would be pressed against respective bus bars. Pressing the first and second sensing conductors onto a common bus bar requires essentially the same alignment precision as probes used on conventional PV cell testers.

For newer PV cells that do not have bus bars, but only fingers on their surfaces, at least one single probe bearing the first and second sensing conductors is pressed against the surface of the PV cell under test such that the first and second sensing conductors extend all across the surface and contact each and every finger. Measurement accuracy can be improved if more than one probe is used, whereupon the measured current values are added together and the measured voltage values are averaged. It is desirable however, to keep the number of probes to a minimum to avoid excessive shade due to the presence of the probes adjacent the front surface of the PV cell during testing.

The first and second sensing conductors may be elongated and may have respective sensing surfaces. The first and second sensing conductors may be supported on a first resiliently deformable support.

The method may involve holding the first and second sensing conductors taut on the first resiliently deformable support.

The method may involve causing the first and second sensing conductors to be pressed against the surface bearing the front side current carrying conductors, such that the sensing surfaces of the first and second sensing conductors are in contact with the surface bearing the front side current carrying conductors along substantially the entire length of the sensing surfaces.

The first resiliently deformable support may be supported for slidable movement and opposite ends of the first resiliently deformable support may be independently urged in a first common direction.

The first resiliently deformable support may be supported on a first common probe.

The above-described method can also be used to make contact with the rear side reference conductor by removably pressing third and fourth parallel spaced apart closely adjacent sensing conductors onto the rear side reference conductor.

The rear side reference conductor may be a flat planar contact formed in the rear surface of the PV cell and may extend across the entire rear surface, or it may be one or more spaced apart silver pads formed on the rear surface. Where the rear side reference conductor is a flat planar conductor, either the above method can be employed, in a manner similar to that described above in connection with the front side, to make contact with the rear side reference conductor or conventional voltage and current probes can be used. Where the rear side reference conductor includes spaced apart silver pads, desirably the above method is used to make contact with one or more of such silver pads.

Where PV cells with rear side silver pads are to be tested, the third and fourth sensing conductors are spaced apart no wider than the silver pads on which they are intended to be pressed to ensure that both the third and fourth sensing conductors simultaneously contact the same silver pad when pressed thereon. Pressing the third and fourth sensing conductors onto a common silver pad requires essentially the same alignment precision as probes used on conventional PV cell testers.

The third and fourth sensing conductors may be elongated and may have respective sensing surfaces and the third and fourth sensing conductors may be supported on a second resiliently deformable support.

The method may involve holding the third and fourth sensing conductors taut on the second resiliently deformable support.

The method may involve causing the third and fourth sensing conductors to be pressed against the rear surface to contact the rear side reference conductor, such that the sensing surfaces of the third and fourth sensing conductors are in contact with the rear side surface along substantially the entire length of the sensing surfaces.

The second resiliently deformable support may be supported for slidable movement and opposite ends of the second resiliently deformable support may be independently urged in a second common direction.

The method may involve supporting the second resiliently deformable support on a second common probe.

Removably pressing the at least one reference contact onto the rear side reference conductor may involve removably pressing pairs of spaced apart current and voltage measuring tips onto the rear side reference conductor, the current measuring tips being connected to the current measurement circuitry and the voltage measuring tip being connected to voltage measurement circuitry as described above.

In accordance with another aspect of the invention, there is provided a probe apparatus for simultaneous measurement of current and voltage output of a PV cell having a front side surface bearing at least one front side current carrying conductor and a rear side surface bearing a rear side current carrying reference conductor. The apparatus includes a first resiliently deformable electrically insulating support, and first and second parallel sensing conductors supported by the resiliently deformable electrically insulated support in closely adjacent spaced apart relation, electrically insulated from each other and operable to be pressed against the front side surface or the rear side surface to contact the front side current carrying conductor or the rear side current carrying reference conductor respectively. The apparatus further includes first and second contacts in electrical contact with the first and second sensing conductors respectively, the first and second contacts being operably configured for connection to current and voltage measuring circuits respectively to connect the first and second parallel sensing conductors to the current and voltage measuring circuits.

The first and second sensing conductors may be elongated and may have first and second sensing surfaces respectively, for contacting the front side surface and the front side current carrying conductor or the rear side surface and the rear side reference conductor.

The apparatus may include a first holder operably configured to hold the first and second sensing conductors taut on the first resiliently deformable support.

The first and second sensing surfaces may have respective lengths and the apparatus may include provisions for causing the first and second sensing conductors to be pressed against the front side surface and the at least one front side current carrying conductor or the rear side surface and the rear side current carrying reference conductor, such that the first and second sensing surfaces contact the front side surface or the rear side surface along substantially their entire length.

The apparatus may include first and second guides operably configured to support opposite ends of the first resiliently deformable support for sliding movement.

The apparatus may include springs operably configured to independently urge opposite ends of the first resiliently deformable support, in a first common direction.

In accordance with another aspect of the invention, there is provided a measurement apparatus for simultaneous measurement of current and voltage output of a PV cell having a front side surface bearing at least one front side current carrying conductor and a rear side surface bearing a rear side current carrying reference conductor. The apparatus includes the probe apparatus described above and includes provisions for removably pressing the first and second sensing conductors, onto the front side surface and the at least one front side current carrying conductor to make electrical contact therewith to facilitate sensing of current and voltage at the at least one front side current carrying conductor by current and voltage measuring circuits. The apparatus further includes at least one reference contact operably configured to be removably pressed onto the rear side surface to contact the reference conductor to make electrical contact therewith to facilitate sensing of current and voltage at the at least one front side current carrying conductor and includes provisions for conducting current from the at least one front side current carrying conductor through the first sensing conductor to the current measurement circuit and back to the reference conductor through the at least one reference contact. The apparatus further includes provisions for connecting the second sensing conductor and the at least one reference contact to the voltage measurement circuit.

The reference contact may include third and fourth parallel spaced apart closely adjacent sensing conductors operably configured to be pressed onto the reference conductor.

The apparatus may include a second resiliently deformable support for supporting the third and fourth sensing conductors. The third and fourth sensing conductors may be elongated and may have respective sensing surfaces for contacting the rear side surface and the reference conductor thereon.

The apparatus may include a second holder operably configured to hold the third and fourth sensing conductors taut on the second resiliently deformable support.

The third and fourth sensing conductors may have sensing surfaces and the apparatus may include provisions for causing the third and fourth sensing conductors to be pressed against the rear side surface and the reference conductor, such that the sensing surfaces of the third and fourth sensing conductors are in contact with the rear side surface along substantially their entire length.

A second support may be operably configured to support the second resiliently deformable support for slidable movement. The second support may have provisions for independently urging opposite ends of the second resiliently deformable support in a second common direction.

The reference contact may include spaced apart voltage and current measuring tips connected to the current and voltage measurement circuitry and operably configured to be pressed against the reference conductor to make contact therewith.

Other aspects and features of the present invention will become apparent to those ordinarily skilled in the art upon review of the following description of specific embodiments of the invention in conjunction with the accompanying figures.

### BRIEF DESCRIPTION OF THE DRAWINGS

In drawings which illustrate embodiments of the invention,

FIG. 1 is a perspective view of an apparatus for simultaneous measurement of current and voltage, according to a first embodiment of the invention.

FIG. 2 is a perspective view of an underside of a PV cell with silver pads on a rear side thereof and operable to be tested by the apparatus shown in FIG. 1.

FIG. 3 is a schematic representation of a power curve of a photovoltaic cell operable to be tested by the apparatus shown in FIG. 1.

FIG. 4 is a side-view of a probe apparatus for use in the measurement apparatus shown in FIG. 1.

FIG. 5 is an oblique view of a representative guide used on the probe shown in FIG. 4.

FIG. 6 is an oblique fragmented view of a first end portion of the probe shown in FIG. 4, seen from a side.

FIG. 7 is an oblique fragmented view of the first end portion shown in FIG. 4, seen from below.

FIG. 8 is an end view of the probe shown in FIG. 4.

FIG. 9 is a schematic representation of electrical circuits formed by use of the apparatus shown in FIG. 1.

### DETAILED DESCRIPTION

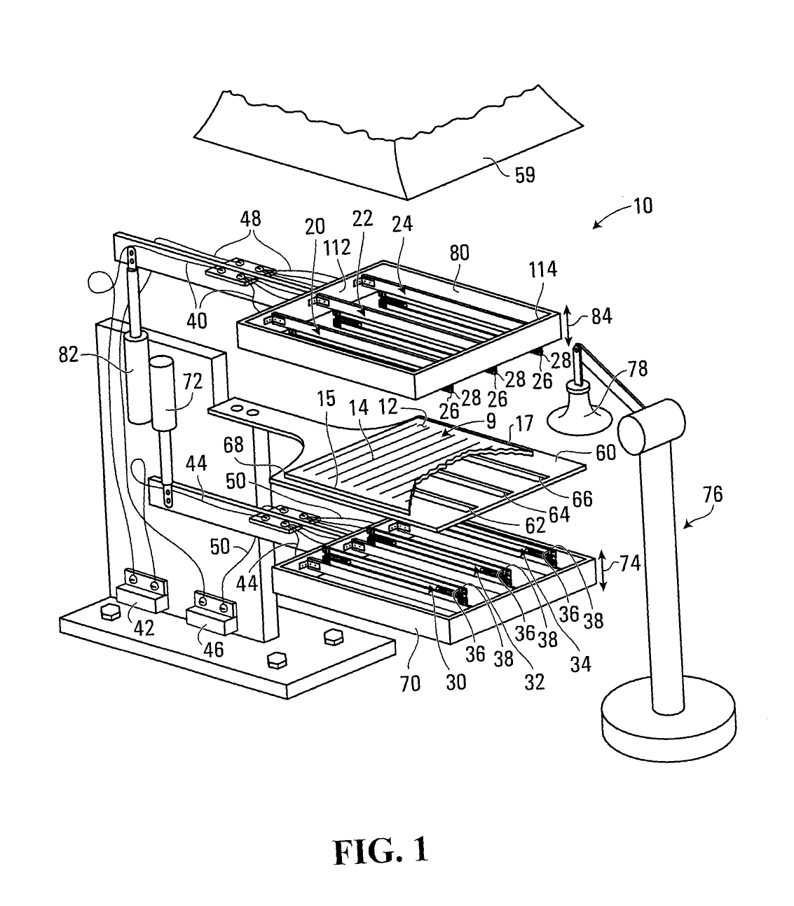

Referring to FIG. 1, a measurement apparatus for simultaneous measurement of current and voltage output of a PV cell 9 is shown generally at 10. The PV cell 9 has a front side surface 12 bearing at least one front side current carrying conductor, which in this embodiment includes a plurality of parallel paced apart “fingers” 14 that have a length such that they extend across nearly the entire length of the PV cell 9 and have a width of about 50 μm, for example. The fingers 14 may be spaced apart by about 1.0 to about 3.0 mm for example.

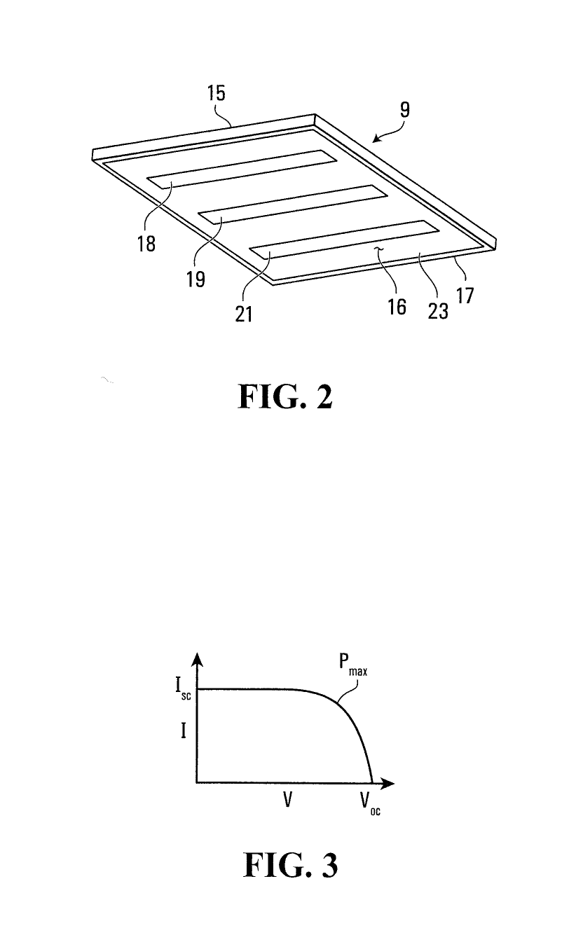

Referring to FIG. 2, the PV cell has a rear surface 16 bearing a rear side current carrying reference conductor, which, in this embodiment, includes first, second and third silver pads 18, 19, and 21 formed on a planar surface of screen-printed aluminum paste 23. The first, second and third silver pads 18, 19 and 21 may have a width of approximately 4.5 mm, for example and are spaced apart such that they generally evenly distribute return current from the load to the PV cell 9, i.e. such that each silver pad distributes about the same amount of current to the cell, assuming the PV cell itself distributes current uniformly throughout. To achieve this, the rear side silver pads 18, 19 and 21 are normally spaced evenly apart. Thus, where there are three silver pads 18, 19 and 21 as shown, the rear side silver pads are desirably positioned such that they are spaced apart by about ¼ of the length of the PV cell 9 and such that the probes nearest first and second ends 15 and 17 of the PV cell are spaced apart from the first and second ends respectively by about ¼ of the length of the PV cell.

The apparatus 10 includes a plurality of front side probes 20, 22, 24, each having first and second parallel closely adjacent sensing conductors 26 and 28 electrically insulated from each other, that are removably pressed against the front side surface 12 transversely to the fingers to make electrical contact with all of the fingers. The number of front side probes is the same as the number of rear side silver pads and the apparatus 10 is configured such that the PV cell 9 under test is positioned on the apparatus such that the front side probes 20, 22 and 24 are aligned to contact the front side of the PV cell 9 directly above the rear side silver pads 18, 19 and 21.

The apparatus 10 also has at least one reference contact that in general is removably pressed against the rear side reference conductor and in this embodiment against the first, second and third silver pads 18, 19 and 21. In this embodiment, the at least one reference contact includes a plurality of rear side probes 30, 32, 34 each having parallel spaced apart closely adjacent third and fourth sensing conductors 36 and 38 that are operable to be removably pressed against one of the first, second and third silver pads 18, 19 and 21 to make electrical contact therewith.

Current is conducted through wires 40 from the first sensing conductors 26 on the front side probes 20, 22, 24 to current measurement circuitry 42, then through wires 44 to the at least one reference contact i.e. the third sensing conductors 36 and then to the silver pads 18, 19 and 21. Voltage is sensed at the second sensing conductor 28 relative to the fourth sensing conductors 38 using voltage measurement circuitry 46 connected to the second and fourth sensing conductors 28 and 38 by wires 48 and 50 respectively.

The first sensing conductors 26 on each of the front side probes 20, 22 and 24 act to collect current from the fingers 14 on the PV cell 9 and act as temporary bus bars for this purpose. Collected current is conveyed by wires 40 to the current measurement circuitry 42 and is conveyed back to the silver pads 18, 19, and 21 by wires 44 and the third sensing conductors 36, to make a complete current measurement circuit of which the PV cell 9 is a part. The second sensing conductors 28 and the fourth sensing conductors 38 and connecting wires 48 and 50 act as voltage probes to the voltage measurement circuitry 46 and measure voltage at the fingers 14 relative to the first, second and third silver pads 18, 19 and 21.

Because the first and second sensing conductors 26 and 28 on each front side probe 20, 22 and 24 are parallel, spaced apart and closely adjacent and because the third and fourth sensing conductors 36 and 38 are similarly arranged on the rear side probes 30, 32 and 34, and because the first and second sensing conductors are electrically insulated and the third and fourth sensing conductors are electrically insulated, independent current and voltage measurement circuits are established when the sensing conductors are pressed against their designated surfaces while at the same time enabling current and voltage to be measured at essentially the same point on the PV cell 9. This virtually eliminates voltage drops between the point at which current is sensed and the point at which voltage is sensed, because, essentially they are the same point. Thus, voltage measurements are independent of the current drawn from the PV cell 9 and this provides for accuracy in measuring the electrical characteristics of a PV cell under test. An accurate power curve such as shown in FIG. 3, for example can be determined for a PV cell 9 under test and this can be used to accurately determine the maximum power output of the PV cell, for example.

To measure the electrical characteristics of the above described PV cell 9 i.e. a PV cell that has no bus bars, current and voltage must be measured under various loading conditions while the PV cell 9 is illuminated with light. Light for this purpose may be provided by a light source such as shown at 59, for example.

The light source 59 is positioned directly above the PV cell 9 under test and projects collimated light onto the front side surface 12 of the PV cell 9 under test.

To effect positioning of the front and front side probes 20, 22 , 24, 30, 32, 34 relative to the PV cell 9 under test, and to position the PV cell to receive collimated light, in the embodiment shown, the PV cell 9 under test is held on a rigid, fixed smooth insulated planar platform 60 having, in this embodiment, first, second and third parallel, spaced apart elongated openings 62, 64 and 66 through which the rear side probes 30, 32 and 34 can pass. The platform 60 may have one or more locators such as a right angled wall portion 68, for example to locate the PV cell 9 on the platform. The elongated openings 62, 64 and 66 are formed in the platform 60 in positions such that the elongated openings are positioned and spaced apart to be directly under the silver pads 18, 19 and 21 respectively, i.e. they are spaced apart by about ¼ of the length of the PV cell 9 and such that the first and third elongated openings are spaced apart from first and second ends of the PV cell by about ¼ of the length of the PV cell.

The rear side probes 30, 32 and 34 are rigidly connected to a rear side frame 70 that holds the rear side probes in parallel spaced apart relation directly beneath corresponding elongated openings 62, 64 and 66. The rear side frame 70 is connected to a rear side actuator 72 operably configured to move the rear side frame 70 and the rear side probes 30, 32 and 34 connected thereto, linearly vertically as shown by arrow 74 to move the rear side probes 30, 32 and 34 up, through respective elongated openings 62, 64 and 66 sufficiently to press the third and fourth sensing conductors 36 and 38 on each rear side probe against the corresponding silver pads 18, 19 and 21 on the rear surface 16 of the PV cell 9. The rear side actuator 72 is also operably configured to cause the rear side frame 70 to move linearly vertically downward after testing to avoid interference with replacement of the cell under test with a new cell to be tested.

Replacement of a cell under test with a new cell to be tested may be effected by suitably configured pick and place equipment such as shown at 76, for example. The pick and place equipment 76 may have a vacuum head, 78 for example, operably configured to selectively pick and place on the platform 60 a PV cell 9 to be tested and to pick a PV cell from the platform after testing and place it in a sorting bin (not shown) or other designated location according to the electrical characteristics of the PV cell just tested.

Tested PV cells may be sorted according to maximum power output, for example. Tested PV cells may be placed by the pick and place equipment into sorting bins associated with output power in 0.25 watt increments, between 13 and 16 watts output, for example. Another bin may be provided to receive PV cells that do not produce a pre-defined minimum power output, i.e. rejects.

The front side probes 20, 22, 24 are rigidly connected to a front side frame 80 that holds the front side probes in parallel spaced apart relation above the PV cell under test. The front side probes 20, 22 and 24 are connected to the front side frame 80 such that they are spaced apart and positioned directly above corresponding rear side probes 30, 32 and 34 respectively. The front side frame 80 is connected to a front side actuator 82 operably configured to move the front side frame 80 and the front side probes 20, 22 and 24 connected thereto, linearly vertically as shown by arrow 84 to move the front side probes 20, 22 and 24 down sufficiently to press the first and second sensing conductors 26 and 28 on each front side probe against the fingers 14 on the front side surface 12 of the PV cell 9. The front side actuator 82 is also operably configured to cause the front side frame 80 to move linearly vertically upward after testing to avoid interference with replacement of the cell under test with a new cell to be tested.

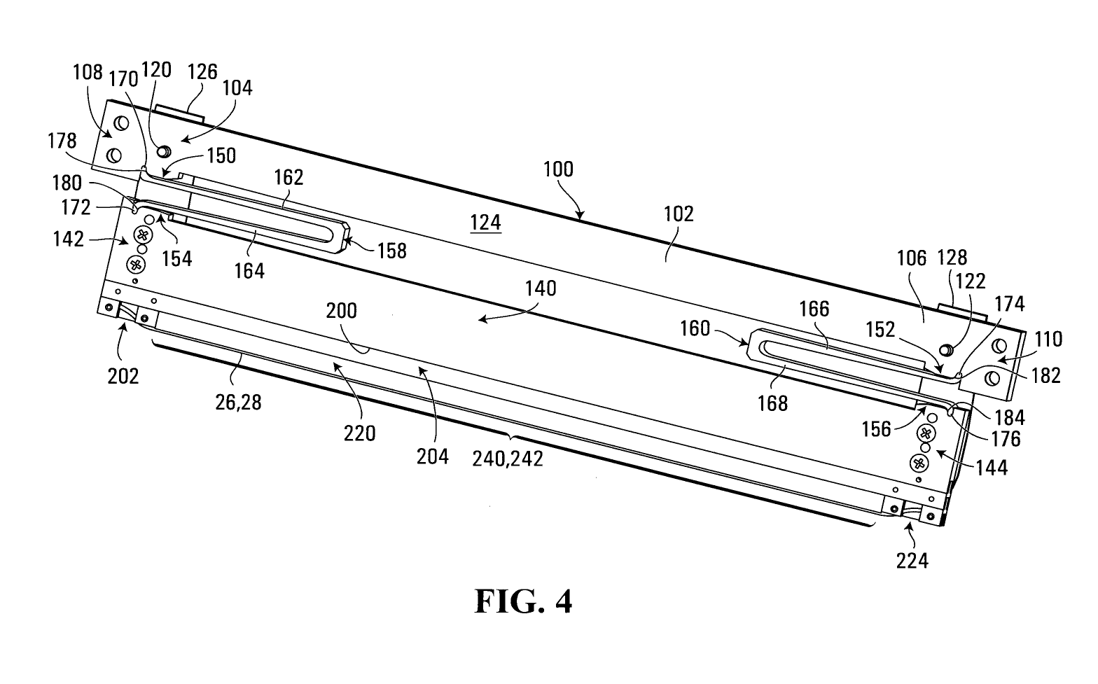

Referring to FIG. 4, an exemplary probe, exemplary of the front side probes 20, 22 and 24 and of the rear side probes 30, 32 and 34 is shown generally at probe 100 and comprises a mounting support 102, which in this embodiment, includes a piece of elongated flat deeply anodized electrically insulated aluminum stock for example, having first and second end portions 104 and 106. The first and second end portions 104 and 106 have respective mounting hole configurations 108 and 110 that are used to securely connect the probe 100 to depending opposite sides 112 and 114 of the front side frame 80 shown in FIG. 1, to hold it securely thereto, for example.

Adjacent and inwardly of the mounting hole configurations 108 and 110, the mounting support 102 has first and second guide pins 120 and 122 on respective second end portions 104 and 106. The first and second guide pins 120 and 122 project outwardly from a broad face 124 of the mounting support 102. Third and fourth guide pins (not shown) similarly project from an opposite broad face (not shown) on the other side (not shown) of the mounting support 102. First and second guides 126 and 128 are disposed on opposite ends of the mounting support 102.

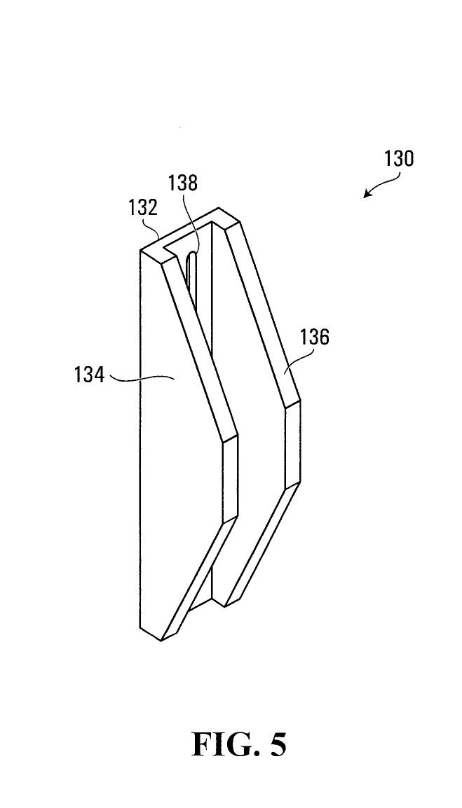

Referring to FIG. 5, a representative guide is shown generally at 130 and includes a back portion 132 and first and second parallel spaced apart side portions 134 and 136 depending therefrom. The back portion 132 has an oblong opening 138 in which one of the guide pins 120 or 122 or one of the guide pins on the opposite side of the mounting support 102 is received.

Referring back to FIG. 4, the probe 100 further includes a movable mount 140. The movable mount 140 is formed from a piece of flat aluminum stock and has first and second end portions 142 and 144. Each of the first and second end portions 142 and 144 has a respective plurality of openings for receiving screws therethrough to secure the respective end portions to respective guides 126 and 128. Thus, the guides 126 and 128 are rigidly connected to the movable mount 140 by screws through the movable mount and are slidably connected to the mounting support 102 by the guide pins (e.g. 120 and 122) on the mounting support received in the oblong openings (138) on the guides. The movable mount 140 and mounting support 102 are thus able to slidably move relative to each other in a direction parallel to a longitudinal axis of the guides 126 and 128, which will be a vertical direction or a direction normal to the front side surface 12 of the PV cell 9 under test, when the probe is in use.

The mounting support 102 has first and second spring retainers 150 and 152 and the movable mount 140 has corresponding first and second spring retainers 154 and 156. A first spring 158 is held in place by the first spring retainers 150 and 154 and a second spring 160 is held in place by the second spring retainers 152 and 156. The first and second springs 158 and 160 have respective arms 162, 164, and 166 and 168, each with a respective end portion 170, 172, 714, 176 that is received and held in a corresponding receptacle 178, 180, 182 and 184 provided by corresponding spring retainers 150, 152, 154, 156. The receptacles 178, 180, 182 and 184 have shapes complementary to the corresponding end portions 170, 172, 714, 176 that they are intended to hold. The first and second springs 158 and 160 operate to urge the movable support away from the mounting support 102.

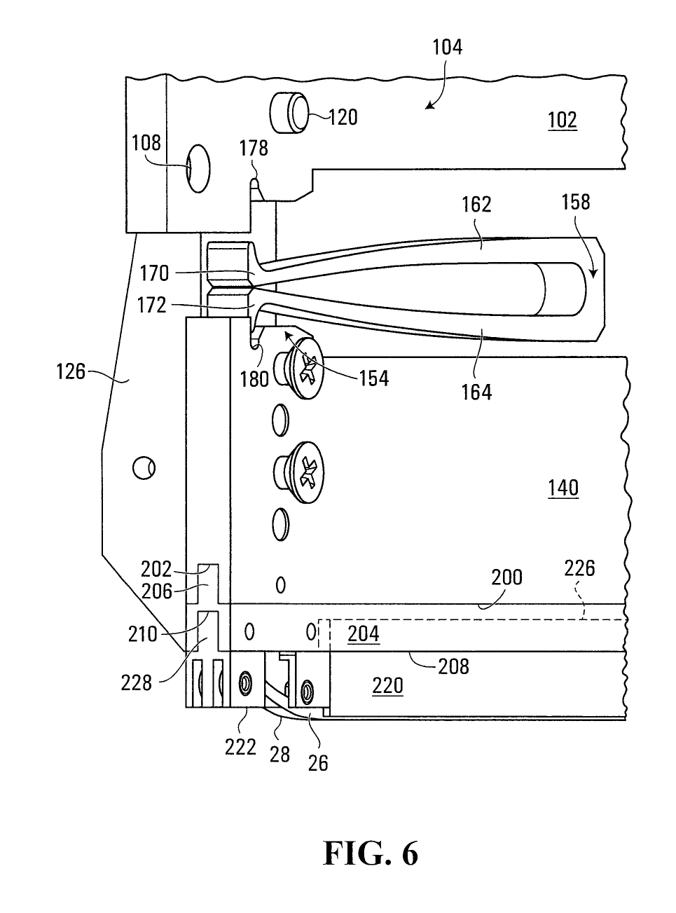

Referring to FIG. 6, the movable mount 140 has a long edge 200 in which is formed a groove 202 which extends the entire length of the movable mount.

The groove 202 enables an intermediate mounting member 204 having a tongue 206 to be connected to the movable mount 140 by insertion of the tongue into the groove 202. The intermediate mounting member 204 further includes an edge 208 having a longitudinally extending groove 210.

Referring back to FIG. 4, the probe 100 further includes a resiliently deformable electrically resilient support 220, hereinafter referred to as a resilient support that supports the first and second sensing conductors 26 and 28 and further includes first and second sensing conductor terminators 222 and 224 at opposite ends of the resilient support 220.

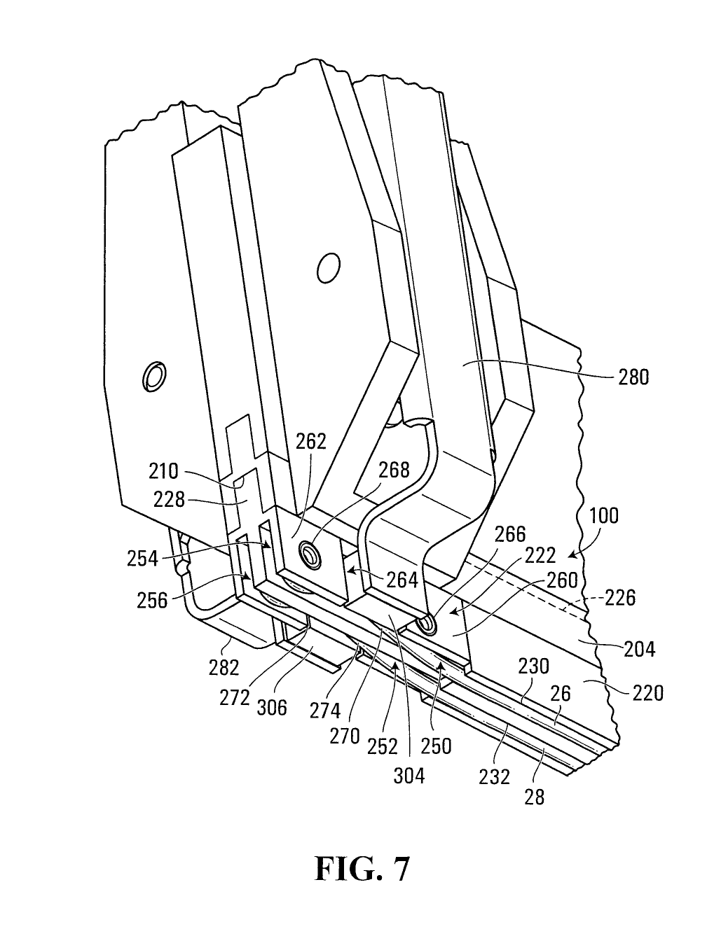

Referring to FIG. 7 the resilient support 220 is made from silicone rubber formed to have a generally rectangular cuboid shape. The silicone rubber is an electrically insulating compound grade, temperature resistant silicone rubber produced from silicone oligomer available from Permatex Canada Inc.

of Ontario Canada for example. This material is inserted into a suitably formed injection mold (not shown) at a pressure of approximately 250 psi and is vulcanized at a temperature of about 120 degrees Centigrade for about 30 minutes to form the resilient support 220.

A first edge of the resilient support 220 has a tongue 226 which is received in the groove 210 to hold the insulating support on the intermediate mounting member 204. The first and second sensing conductor terminators 222 (and 224) also have respective tongues, only one of which is shown at 228 in FIG. 7, operable to be received in the groove 210, for holding the first and second sensing conductor terminators 222 (and 224) on the intermediate mounting member 204 in the position shown in FIG. 4. The resilient support 220 is thus held on the intermediate mounting member 204, between and adjacent the first and second sensing conductor terminators 222 and 224.

Referring back to FIG. 7, the resilient support 220 has an outer edge opposite the edge having the tongue 226, and this outer edge has first and second spaced apart but closely adjacent parallel longitudinally extending grooves 230 and 232 and that extend the entire length of the resilient support 220. Portions of the first and second sensing conductors 26 and 28 are held in the first and second grooves 230 and 232 respectively. Thus, the first and second sensing conductors 26 and 28 are supported by the resilient support 220 in closely adjacent spaced apart relation, electrically insulated from each other. Referring back to FIG. 4, the first and second sensing conductors 26 and 28 have sensing surfaces 240 and 242 having respective lengths that extend the entire length of the resilient support 220 and it is these sensing surfaces that are pressed onto the front side surface (12) of the PV cell (9) to contact the fingers (14).

The term “closely adjacent and spaced apart” is intended to mean that longitudinal centerlines of the first and second sensing conductors 26 and 28 are within a few wire widths of each other. A wire width may be defined as the average diameter of the first and second sensing conductors 26 and 28, in the case where the sensing conductors are circular in cross section, for example.

The first and second sensing conductors 26 and 28 need not be circular in cross section however and could be rectangular in cross section, for example, in which case the wire width may be the width of the sensing conductors. Or if desired, the widths of the first and second sensing conductors 26 and 28 can be relatively wide and the distance between such conductors can be relatively small. The selection of wire cross section shape, width and spacing will depend very much on the application.

For example, where the probe 100 is to be used to measure current and voltage of a PV cell having bus bars, the probe will be oriented such that the first and second sensing conductors 26 and 28 are parallel with the bus bar they are intended to contact. For accurate measurements, the wire width and spacing must be selected such that substantially the entire length of the sensing surfaces 240, 242 of the first and second sensing conductors 26, 28 will contact substantially the entire length of the bus bar, when the sensing surfaces are placed in contact with the bus bar. In this case, since bus bars are only about 2 mm wide, first and second sensing conductor diameters and spacing of about 0.7 mm and 0.2 mm or less would be suitable.

However, where the PV cell 9 under test has no bus bars and instead only fingers 14 on the front side surface 12, as in the embodiment shown, the probe and first and second sensing conductors 26 and 28 are oriented perpendicularly to the orientation of the fingers 14 and thus there is no requirement to precisely align the sensing conductors with the fingers. In this case, the diameter and spacing of the first and second sensing conductors 26 and 28 is not critical, but it will be desirable to keep the first and second sensing conductors relatively close to each other to avoid measurement errors due to voltage drops in the segments of the fingers 14 between the first and second sensing conductors 26 and 28. Therefore, in this case the spacing and diameter of the first and second sensing conductors 26 and 28 could be 0.2 mm and 0.7 mm respectively as it might be if it were used with a PV cell having bus bars of about 2 mm width.

It will be appreciated that it may be advantageous to cause the diameter and spacing of the first and second sensing conductors 26 and 28 on a probe 100 to be suitable for use in measuring electrical characteristics of a PV cell with bus bars, because that same probe can also be used to measure the electrical characteristics of a PV cell without bus bars.

In the embodiment shown, the first and second sensing conductors 26 and 28 have respective opposite ends, only first ends 250 and 252 of which are shown in FIG. 7. The first sensing conductor terminator 222 has parallel spaced apart slots 254 and 256 in which are received the first ends 250 and 252 of the first and second sensing conductors 26 and 28 respectively.

The first sensing conductor terminator 222 (and the second sensing conductor terminator 224 shown in FIG. 4) is formed from ceramic material such as porcelain, alumina ceramics, chromium oxide ceramics or titanium ceramics, for example, to provide a rigid, electrically insulating terminator for terminating the first ends 250 and 252 of the first and second sensing conductors 26 and 28 while maintaining the first and second sensing conductors in closely adjacent parallel spaced apart relation at the second end portion 104 of the probe 100.

The first sensing conductor terminator 222 has a guide portion 260 and an anchor portion 262 disposed on opposite sides thereof, but spaced apart to provide a space 264 therebetween. The first end 250 of the first sensing conductor 26 is routed through the guide portion 260 to extend over a guide pin 266, through the space 264 and into the anchor portion 262 where it is wrapped around an anchor pin 268 which secures the first end 250 to the first sensing conductor terminator 222. A second end (not shown) of the first sensing conductor 26 is terminated in a similar manner to the second sensing conductor terminator (224 in FIG. 4) the same as the first sensing conductor terminator 222 and thus the first sensing conductor 26 is held taut throughout its entire length, by the first and second sensing conductor terminators 222 and 224.

The first and second ends of the second sensing conductor 28 are terminated in the same way, to the same first and second sensing conductor terminators 222 and 224 to ensure the second sensing conductor is held taut throughout its entire length. The guide pin 266 and the anchor pin 268 are insulators, which enables the same pins to guide and anchor respective first ends 250 and 252 of the first and second sensing conductors 26 and 28. The same is true at the second sensing conductor terminator 224.

It will be appreciated from the foregoing that the first end 250 of the first sensing conductor 26 is routed through the space 264 which leaves a portion of the first end 250 exposed and thus the first end has a first exposed portion 270. A similar space 272 is formed on an opposite side of the first sensing conductor terminator 222, through which a similar second exposed portion 274 of the first end 252 of the second sensing conductor 28 extends.

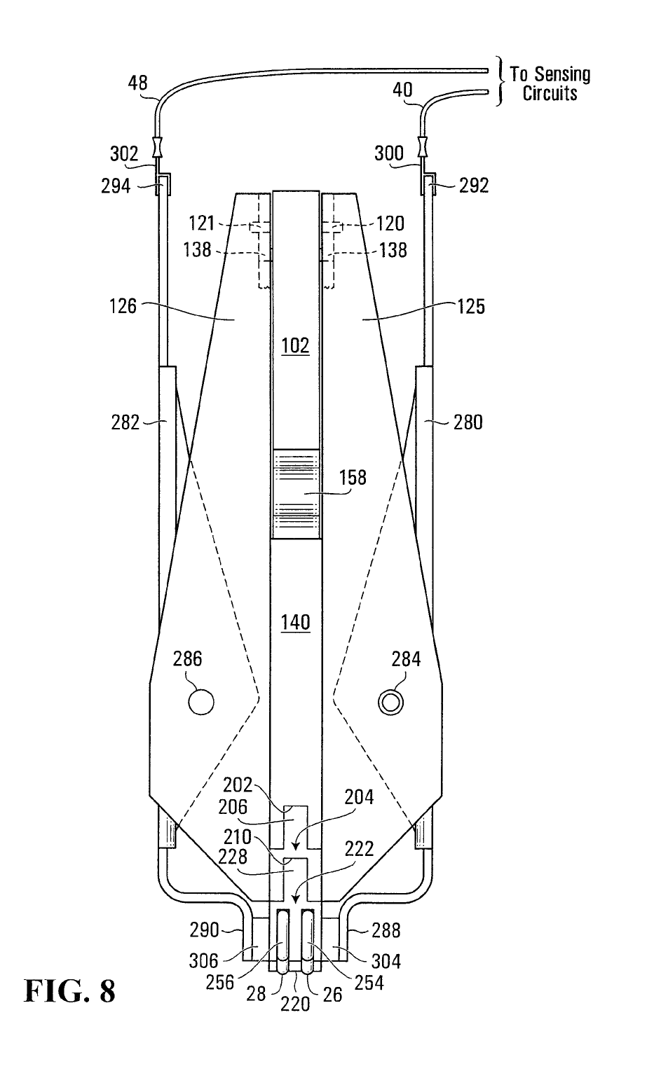

Referring to FIG. 8, as described above, guides 125 and 126 of the type shown at 130 in FIG. 5 are securely connected to the movable mount 140 on opposite sides thereof. As described above, the first and second guide pins 120 and 121 are received through corresponding oblong openings 138 in the back portions (132) of respective guides 125 and 126 to facilitate movement of the mounting support 102 toward and away from the movable mount 140 (up and down in the drawings). The springs, only one of which is shown at 158 in FIG. 8 urge the movable mount 140 and the mounting support 102 away from each other.

The probe 100 further includes first and second pivot arms 280 and 282 pivotally connected to respective guides 125 and 126 by pivot pins 284 and 286 respectively. In this embodiment, each pivot arm 280 and 282 has a respective contact end 288 and 290 respectively and a connection end 292 and 294 respectively. The pivot arms 280 and 282 are made from copper having a corrosion-resistant plating to facilitate direct connection of wire terminals 300 and 302 to the connection ends 292 and 294, for example.

The contact ends 288 and 290 are generally S-shaped and have contact blocks 304 and 306 respectively secured thereto. The contact blocks 304 and 306 may be made from silver, for example.

The guides 125 and 126 and pivot arms 280 and 282 are positioned such that the contact blocks 304 and 306 are operable to be received in the spaces 264 and 272 (seen in FIG. 7) to make direct contact with the exposed portions 270 and 272 (seen best in FIG. 7) respectively of the first and second sensing conductors 26 and 28 respectively. Springs, not shown, are used to urge the pivot arms 280 and 282 to push the contact blocks 304 and 306 into the spaces 264 and 272 to cause the contact blocks to make direct electrical contact with the exposed portions 270 and 272 respectively of the first and second sensing conductors 26 and 28 respectively. Thus, the first and second contact blocks 304 and 306 are in direct electrical contact with the first and second sensing conductors 26 and 28 and the first and second connection ends 292 and 294 are in direct electrical connection with the contact blocks.

The first and second sensing conductors 26 and 28 are made from 99% pure silver to prevent corrosion and provide resistance to abrasion that can occur during use. The first and second contact blocks 246 and 248 are made from the same material to avoid electrolytic reaction with the first and second sensing conductors 26 and 28.

The connection ends 292 and 294 of the pivot arms 280 and 282 are connected to wire terminals 300 and 302 respectively which are used to connect the probe to the current and voltage measurement circuitry 42 and 46.

In an alternate embodiment, the first and second contact blocks 246 and 248 may be eliminated and the contact ends 288 and 290 may be permanently electrically connected directly to the first ends 250 and 252 of the first and second sensing conductors 26 and 28 such as by soldering. Alternatively, other methods of connecting the first and second sensing conductors 26 and 28 to wires connected to the current and voltage measurement circuitry 42 and 46 may be used. Such methods may include connecting wires connected to the current and voltage measurement circuitry 42 and 46 directly to protruding end portions (not shown) of the first and second sensing conductors 26 and 28, for example.

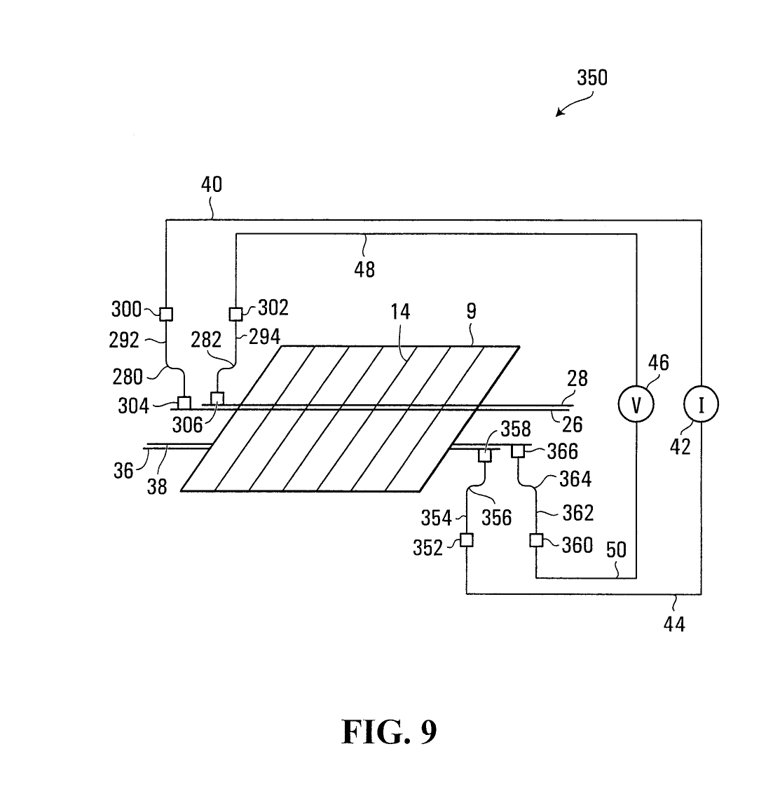

While the above description in is the context of a front side probe, front side probes may be used upside down and connected to the rear side frame 70 to become rear side probes as shown at 30, 32 and 34 in FIG. 1. To distinguish the first and second sensing conductors 26 and 28 on a probe used for the front side from the same conductors on a probe used for the rear side, the first and second conductors are referred to as first and second conductors when referring to a front side probe and these same conductors on a probe used as a rear side probe are referred to herein as third and fourth sensing conductors. Using the above terminology, a simplified schematic diagram of circuits formed by using probes of the type described herein and by using the apparatus described herein, is shown generally at 350 in FIG. 9.

The mechanical structure of the probes is omitted for better clarity. The first and second sensing conductors 26 and 28 on front side probe (20) are shown extending across the PV cell 9, in contact with the fingers 14 of the PV cell. All of the front side probes are the same, so only one will be described. The first sensing conductor 26 is connected via the contact block 304 to the first arm 280 and the connection end 292 of the first arm 280 is connected to the wire terminal 300. The wire 40 connects the wire terminal 300 to the current measurement circuitry 42. The current measurement circuitry 42 is further connected to the return wire 44 which is connected to a wire connector 352 which is connected to an end 354 of a third arm 356 on the rear side probe (30) that has a contact block 358 in contact with the third sensing conductor 36 on the rear side probe.

Similarly, the second sensing conductor 28 is connected via the contact block 306 to the second arm 282 and the connection end 294 of the second arm 282 is connected to the wire terminal 302. The wire 48 connects the wire terminal 302 to the voltage measurement circuitry 46. The voltage measurement circuitry 46 is further connected to the return wire 50 which is connected to a wire connector 360 which is connected to an end 362 of a third arm 364 on the rear side probe (30) and a contact block 366 on the third arm is in contact with the fourth sensing conductor 38 on the rear side probe.

FIG. 9 depicts the electrical connections of only one front side probe and only one rear side probe with the PV cell 9 under test. The electrical connections of the remaining front side probes to the PV cell 9 under test are the same, with respective wire terminals (like 300 and 302) on the remaining front side probes connected in parallel with corresponding ones of the wire terminals 300 and 302 shown. Similarly, the electrical connections of the remaining rear side probes to the PV cell are the same, with respective wire connectors (like 352 and 360) on the remaining rear side probes being connected in parallel with corresponding ones of the wire connectors 352 and 360 shown.

As will be appreciated from above and with reference to FIG. 9, two separate circuits are established for separate and simultaneous measurement of voltage and current at the fingers relative to the reference contact, without any noticeable influence on each other. For example, in the current measurement circuit, current on the order of a few amperes flows through the circuit with attendant voltage drops in each wire and component in the current sensing circuit. Since the current measurement apparatus is only concerned with measuring current, a simple low-impedance shunt can be used as the test load to accurately measure current drawn from the PV cell 9. At the same time, in the voltage measurement circuit virtually no current will flow since the voltage measurement circuitry 46 will have a high impedance. Therefore voltage measurements are not dependent, (i.e. they are independent of current drawn from the PV cell 9) which allows for simultaneous accurate voltage and current measurements right at the fingers 14 of the PV cell 9, for use in determining the electrical characteristics of the cell. Thus, a plurality of PV cells can be tested using a common, uniform test, independent of, and uninfluenced by connection circuitry, to determine the individual electrical characteristics of the PV cells. This enables the individual electrical characteristics of the PV cell to be accurately determined and facilitates better, more accurate classification and ultimately matching of cells to be used in a common PV module.

Referring back to FIG. 1, to use the apparatus, a PV cell 9 to be tested is positioned on the platform 60 as shown, by the pick and place equipment 76. The rear side actuators 72 and 82 are then operated to move the rear and front side frames 70 and 80 up and down respectively, toward the PV cell 9 until the rear side probes 30, 32 and 34 extend through the elongated openings 62, 64 and 66 in the plafform and the first and second sensing conductors 26 and 28 on each of the front side probes are pressed against the fingers 14 on the PV cell while at the same time each of the third and fourth sensing conductors 36 and 38 on each of the rear side probes 30, 32 and 34 is pressed against a respective silver pads 18, 19 and 21. This completes current and voltage measurement circuits involving the current measurement circuitry 42 and the voltage measurement circuitry 46. The current measurement circuitry 42 detects the presence of a PV cell and communicates with the light source 59 to turn the light on.

The PV cell 9 is then illuminated by the light source 59 and current is conducted from the fingers 14 through the first sensing conductors 26 to the current measurement circuitry 42 and through the third sensing conductors 36 back to the silver pads 18, 19 and 21 to enable the current measurement circuitry to measure the current produced by the PV cell. At the same time, the voltage at the fingers 14 relative to the silver pads 18, 19 and 21 is sensed by the voltage measuring circuitry 46, using the second and fourth sensing conductors 28 and 38 as voltage probes.

The current measurement circuitry 42 presents various test loads to the PV cell 9 under test while simultaneously measuring current and at the same time communicating with the voltage measurement circuitry 46 to acquire Voltage values for each test load, while the PV cell is illuminated with light. These voltage (V) and current (I) values are plotted as an I-V graph as shown in FIG. 3 and allow the main characteristics of the PV cell, including but not limited to, short circuit current, (Isc), open circuit voltage (Voc), fill-factor (FF), maximum power point (Pmax), electric current at maximum power point (Imax), voltage at maximum power point (Vmax), shunt resistance (Rsh), and series resistance (Rs) to be determined.

The current measurement circuitry 42 then communicates with the light source 59 to turn the light off and then communicates with the pick and place equipment 76 to communicate a representation of the maximum power value of the PV cell 9 to the pick and place equipment. The pick and place equipment 76 determines the physical location of a storage bin associated with the measured maximum power value and then picks the PV cell 9 from the platform 60 and places it in the determined storage bin. The pick and place equipment 76 then picks another PV cell from a stack of PV cells queued for testing and places it on the platform 60 for testing and sorting as described above.

Referring to FIG. 4, it will be appreciated that the springs 158 and 160 on opposite ends of the probe 100 provide for “leveling” of the probe to the surface of the PV cell (9) to cause the first and second sensing conductors (26 and 28) to be urged onto the fingers (14) of the PV cell throughout their entire length, to ensure the sensing surfaces 240 and 242 come in contact with all of the fingers across the front side surface 12 of the PV cell.

Alternatively other methods for “leveling” of the probe to the surface of the PV cell may be employed including for example use of a set of springs (not shown) between the mounting support 102 and movable mount 140 either in addition to springs 158 and 160 or instead, for example. The resilient support (220) on which the first and second sensing conductors 26 and 28 are held also helps to ensure all of the fingers across the front side surface 12 are contacted by the first and second sensing conductors (26 and 28) and in a case where the positioning of the probe 100 relative to the PV cell 9 is repeatably level to the front side surface 12, the springs 158 and 160 may not be necessary and may be omitted. In this case the resilience of the resilient support is used to ensure the sensing surfaces 240 and 242 are in contact with each of the fingers.

In general, the first and second sensing conductors 26 and 28 on each of the front side probes 20, 22 and 24 are removably pressed onto the fingers 14 of the PV cell 9, by positioning the probe 100 on the front side surface 12 of the PV cell such that at least the resilient supports 220 on each probe are resiliently deformed and optionally such that the springs 158 and 160 on each probe are compressed, if provided, to ensure the first and second sensing conductors on each probe make electrical contact with all of the fingers to facilitate sensing of voltage and current by the current and voltage measurement circuitry 42 and 46. Similarly the third and fourth sensing conductors 36 and 38 on each of the rear side probes 30, 32 and 34 are pressed against corresponding silver pads 18, 19 and 21 such that the resilient supports (220) supporting the third and fourth sensing conductors are deformed and such that the first and second springs 158 and 160 are deformed, if provided, to ensure that substantially all of the sensing surfaces 240 and 242 of the third and forth sensing conductors contact the corresponding silver pads to ensure a good contact therewith.

Using the process described above the above apparatus 10 can be used to accurately determine the electrical characteristics of a PV cell that has no bus bars and has silver pads on a rear surface thereof.

Alternatively, the apparatus 10 can be adapted to measure the electrical characteristics of a PV cell without front side bus bars and having a flat planar contact formed in the rear surface of the PV cell and extending across the entire rear surface, instead of spaced apart silver pads formed on the rear surface. In this case, the flat planar conductor on the rear surface acts as the reference conductor of the PV cell and contacting the flat planar conductor anywhere amounts to contacting the reference conductor. Therefore, one or more of the rear side probes 30, 32 and 34 described above can be used to make contact with this reference conductor for this type of PV cell, or alternatively one or more probes with conventional current and voltage measurement heads can be used.

When measuring the electrical characteristics of a PV cell that has no bus bars and a flat planar reference conductor on the rear side it is desirable to minimize shading of the front side surface 12 of the PV cell 9 under test by parts of the measurement apparatus and therefore it is desirable to minimize the number of front side probes 20, 22 and 24 while at the same time providing sufficient current carrying capacity in the first sensing conductors 26 and in the third sensing conductors 36 to carry the current generated by the PV cell under test away from the cell to the current measurement circuitry 42. At least one front side surface probe is required and in the embodiment described, three are shown to illustrate how multiple probes can be used.

Where multiple probes are to be used, it is desirable to space the front side probes 20, 22 and 24 apart such that they evenly gather current from the fingers 14 of the PV cell 9, i.e. such that each probe gathers about the same amount of current, assuming the PV cell produces current uniformly across its front side surface 12. Generally this means spacing the front side probes 20, 22 and 24 evenly apart. Thus, where there are three probes as shown, the front side probes 20, 22 and 24 are desirably positioned such that they are spaced apart from an adjacent probe by about ¼ of the length of the PV cell 9 and such that the probes nearest first and second ends 15 and 17 of the PV cell are spaced apart from the first and second ends respectively by about ¼ of the length of the PV cell.

The number of rear side probes should correspond to the number of front side probes because the front side probes 20, 22, 24 are pressed against certain locations on the front side surface 12 of the PV cell 9 under test and thus exert a force on the PV cell and this force can be counterbalanced by causing the rear side probes 30, 32 and 34 to contact the rear surface 16 in locations on the rear side directly beneath locations at which corresponding front side probes 20 , 22 and 24 contact the front side surface 12. This reduces the risk of cracking the PV cell 9 that can occur due to the act of pressing the front and/or rear side probes against the front side and/or rear surfaces 12 and 16 of the cell.

Alternatively, where the PV cell has a flat planar conductor formed in the rear surface thereof, conventional probes employing a plurality of pairs of current and voltage measuring tips arranged in a linear fashion, may be substituted for the rear side probes shown in FIG. 1. Electrically, substitution of conventional probes for the rear side probes described above is possible, but where conventional rear side probes are to be used, it is desirable that they be aligned the same as the rear side probes described in the above embodiment to balance the pressure exerted on the PV cell 9 by the front side probes 20, 22 and 24.

In another alternative embodiment, for use in testing PV cells with a flat planar rear side reference conductor, only a single pair of conventional current and voltage measuring tips connected to the current and voltage measurement circuitry 42 and 46 respectively is used as the at least one reference contact, although care must be taken to balance the pressure of the front side probes on the PV cell with the pressure of the rear side probe comprising the single pair of current and voltage measuring tips, to avoid damaging the PV cell due to the pressure. Use of a single pair of current and voltage measuring tips may not be practical where a plurality of front side probes of the type described above is used, because the pressure of each front side probe would not be directly balanced by a corresponding probe on the rear side of the PV cell. However, modifications to the platform, such as by providing only a single central opening, for example, to receive the conventional probe comprising a pair of conventional current and voltage tips, may overcome this mechanical problem. In any event at least one reference contact will be required to contact the rear side reference conductor to complete the current and voltage measurement circuitry.

The apparatus 10 can also be used to accurately determine the electrical characteristics of a PV cell (not shown) that has bus bars on the front side surface and silver pads on the rear side surface by causing the PV cell under test to be accurately located relative to the front and front side probes 20, 22, 24, and 30, 32, 34 and arranging the front side probes 20, 22, 24 to be parallel and aligned with respective bus bars so as to cause the first and second sensing conductors 26 and 28 on the front side probes 20, 22, 24 to contact the surfaces of bus bars associated with respective probes while causing the rear side probes 30, 32 and 34 to contact respective silver pads of the PV cell. Ideally the silver pads will be located on the PV cell in positions directly opposite and corresponding to the positions of front side bus bars, on the rear side of the PV cell under test.

From the foregoing it should be appreciated that the apparatus and probes described herein can be used to measure the electrical characteristics of various types of PV cells including those having no bus bars on the front side surface or those having bus bars and those having silver pads or those having a flat planar reference conductor on the rear side surface.

While specific embodiments of the invention have been described and illustrated, such embodiments should be considered illustrative of the invention only and not as limiting the invention as construed in accordance with the accompanying claims.

1. A method for simultaneous measurement of current and voltage output of photovoltaic (PVA cells having a front side surface bearing at least one front side current carrying conductor and a rear surface bearing a rear side current carrying reference conductor, the method comprising:
removably pressing first and second parallel spaced apart closely adjacent sensing conductors, electrically insulated from each other, onto the front side current carrying conductor to make electrical contact therewith;
removably pressing at least one reference contact to the rear side reference conductor to make electrical contact therewith;
conducting current from the current carrying conductor through the first sensing conductor to current measuring circuitry and through said at least one reference contact back to the rear side reference conductor; and
sensing a voltage at the second sensing conductor relative to the rear side reference conductor, using voltage measuring circuitry.

2. The method of claim 1 wherein said first and second sensing conductors are elongated and have respective sensing surfaces and wherein the method further comprises supporting the first and second sensing conductors on a first resiliently deformable support.

3. The method of claim 2 further comprising holding said first and second sensing conductors taut on said first resiliently deformable support.

4. The method of claim 2 further comprising causing said first and second sensing conductors to be pressed against said surface bearing said front side current carrying conductor, such that said sensing surfaces of said first and second sensing conductors are in contact with said surface bearing said front side current carrying conductor along substantially the entire length of said sensing surfaces.

5. The method of claim 4 wherein causing comprises supporting said first resiliently deformable support for slidable movement and independently urging opposite ends of said first resiliently deformable support in a first common direction.

6. The method of claim 5 further comprising supporting said first resiliently deformable support on a first probe.

7. The method of claim 1, wherein removably pressing said at least one reference contact to the rear side reference conductor comprises removably pressing third and fourth parallel spaced apart closely adjacent sensing conductors onto the rear side reference conductor.

8. The method of claim 7 wherein said third and fourth sensing conductors are elongated and have respective sensing surfaces and wherein the method further comprises supporting the third and fourth sensing conductors on a second resiliently deformable support.

9. The method of claim 8 further comprising holding said third and fourth sensing conductors taut on said second resiliently deformable support.

10. The method of claim 8, further comprising causing said third and fourth sensing conductors to be pressed against said rear surface to contact said rear side reference conductor, such that said sensing surfaces of said third and fourth sensing conductors are in contact with said rear side surface along substantially the entire length of said sensing surfaces.

11. The method of claim 10 wherein causing comprises supporting said second resiliently deformable support for slidable movement and independently urging opposite ends of said second resiliently deformable support in a second common direction.

12. The method of claim 11 further comprising supporting said second resiliently deformable support on a second probe.

13. The method of claim 1, wherein removably pressing said at least one reference contact onto the rear side reference conductor comprises removably pressing spaced apart pairs of current and voltage measuring tips onto the rear side reference conductor, said current measuring tips being connected to the current sensor and said voltage measuring tips being connected to voltage measurement circuitry.

14. A probe apparatus for simultaneous measurement of current and voltage output of a PV cell having a front side surface bearing at least one front side current carrying conductor and a rear side surface bearing a rear side current carrying reference conductor, the apparatus comprising:
a first resiliently deformable electrically insulating support;
first and second parallel sensing conductors supported by the resiliently deformable electrically insulated support in closely adjacent spaced apart relation, electrically insulated from each other and operable to be pressed against at said front side surface or said rear side surface to contact said front side
current carrying conductor or said rear side current carrying reference conductor respectively; and
said first and second parallel sensing conductors being operably configured for connection to current and voltage measuring circuits respectively to connect said first and second parallel sensing conductors to current and voltage measuring circuits respectively.

15. The apparatus of claim 14 wherein said first and second sensing conductors are elongated and have first and second sensing surfaces respectively, for contacting said front side surface and said front side current carrying conductor or said rear side surface and said rear side reference conductor.

16. The apparatus of claim 15 further comprising a first holder operably configured to hold said first and second sensing conductors taut on said first resiliently deformable support.

17. The apparatus of claim 15, wherein said first and second sensing surfaces have respective lengths and wherein the apparatus further comprises means for causing said first and second sensing conductors to be pressed against said front side surface and said at least one front side current carrying conductor or said rear side surface and said rear side current carrying reference conductor, such that said first and second sensing surfaces contact said front side surface or said rear side surface along substantially their entire length.

18. The apparatus of claim 17 further comprising first and second guides operably configured to support opposite ends of said first resiliently deformable support for sliding movement.

19. The apparatus of claim 18 further comprising springs operably configured to independently urge said opposite ends of said first resiliently deformable support, in a first common direction.

20. A measurement apparatus for simultaneous measurement of current and voltage output of a PV cell having a front side surface bearing at least one front side current carrying conductor and a rear side surface bearing a rear side current carrying reference conductor, the apparatus comprising:
the apparatus of claim 14; and
means for removably pressing said first and second sensing conductors, onto the front side surface and said at least one front side current carrying conductor to make electrical contact therewith to facilitate sensing of current and voltage at the at least one front side current carrying conductor by the current and voltage measuring circuits;
at least one reference contact operably configured to be removably pressed onto the rear side surface to contact the reference conductor to make electrical contact therewith to facilitate said sensing of current and voltage at the at least one front side current carrying conductor;
means for conducting current from the at least one front side current carrying conductor through the first sensing conductor to the current measurement circuit and back to the reference conductor through said at least one reference contact; and
means for connecting the second sensing conductor and said at least one reference contact to said voltage measurement circuit.

21. The apparatus of claim 20 wherein said at least one reference contact includes third and fourth parallel spaced apart closely adjacent sensing conductors operably configured to be pressed onto the reference conductor.

22. The apparatus of claim 21 further comprising a second resiiiently deformable support for supporting said third and fourth sensing conductors and wherein said third and fourth sensing conductors are elongated and have respective sensing surfaces for contacting the rear side surface and the reference conductor thereon.

23. The apparatus of claim 22 further comprising a second holder operably configured to hold said third and fourth sensing conductors taut on said second resiliently deformable support.

24. The apparatus of claim 21, wherein said third and fourth sensing conductors have sensing surfaces and wherein said apparatus further comprises means for causing said third and fourth sensing conductors to be pressed against said rear side surface and said reference conductor, such that said sensing surfaces of said third and fourth sensing conductors are in contact with said rear side surface along substantially their entire length.

25. The apparatus of claim 24 further comprising;
a second support operably configured to support said second resiliently deformable support for slidable movement; and
means for independently urging opposite ends of said second resiliently deformable support in a second common direction.

26. The apparatus of claim 20 wherein said at least one reference contact comprises spaced apart voltage and current measuring tips connected to said current and voltage measurement circuitry and operably configured to be pressed against said reference conductor to make contact therewith.
